(19) United States
(12) Patent Application Publication
(10) Pub. No.: US 2025/0040114 A1
(43) Pub. Date: Jan. 30, 2025

(54) Recording and Evaluating Parameter Values in an Electronics Production Line

(71) Applicant: Siemens Aktiengesellschaft, München (DE)

(72) Inventors: Rudiger Knofe, Teltow (DE); Martin Franke, Berlin (DE); Bernd Müller, Falkenberg (DE); Rene Blank, Berlin (DE); Peter Frühauf, Falkensee (DE); Stefan Nerreter, Heidesee OT Blossin (DE); Matthias Heimann, Potsdam (DE); Ulrich Wittreich, Velten (DE); Carsten Borwieck, Berlin (DE)

(73) Assignee: Siemens Aktiengesellschaft, München (DE)

(21) Appl. No.: 18/713,869

(22) PCT Filed: Sep. 22, 2022
(86) PCT No.: PCT/EP2022/076390

§ 371 Date: May 28, 2024

(30) Foreign Application Priority Data
Nov. 30, 2021 (EP) 21211365.8

(51) Int. Cl. H05K 13/08

(52) U.S. Cl. CPC H05K 13/0882; H05K 13/083; H05K 13/084

(57) ABSTRACT

Various embodiments of the teachings herein include methods for recording and evaluating parameter values in an electronics production line to produce electronic assemblies, the production line including a dispenser for applying joining material to a component carrier, a placement device for placing electronic components on the component carrier, and a joining device to join the electronic components to the component carrier. An example method includes: receiving a parameter value from each of the devices; and storing the parameter values in a dataset associated with a defined number of component carrier and with the resulting assemblies.

### CROSS-REFERENCE TO RELATED APPLICATIONS

This application is a U.S. National Stage Application of International Application No. PCT/EP2022/076390 filed Sep. 22, 2022, which designates the United States of America, and claims priority to EP application Ser. No. 21/211,365.8 filed Nov. 30, 2021, the contents of which are hereby incorporated by reference in their entirety.

### TECHNICAL FIELD

The present disclosure relates to recording and evaluating parameter values of at least one electronics production line. Various embodiments of the teachings herein include methods for producing electronic assemblies and systems for recording parameter values.

### BACKGROUND

An electronics production line is designed to produce electronic assemblies and has here a number of devices, including a device for applying joining material, for example a stencil printer for solder and/or sinter pastes or joining material dispensing machines. The devices for applying joining material are designed here in such a way that an applicable joining material is applied to a component carrier, for example a PCB or ceramic substrate, in each case at the points at which electrical components are then provided and ultimately joined. Furthermore, the production line has a placement device designed to place electronic components on the component carriers provided with joining material. The placement devices may be automatic placement machines for SMD components and other electronic components. The production line furthermore has a joining device designed to join the electronic components to the component carriers. Such joining devices may be, for example, reflow furnaces or wave and/or selective soldering systems for THT components.

### SUMMARY

The teachings of the present disclosure may be used to improve and simplify the recording and in particular the evaluation of parameter values. For example, some embodiments of the teachings herein include a method for recording and evaluating parameter values in at least one electronics production line (200), the electronics production line (200) being designed to produce electronic assemblies (1,2) and having at least the following devices (20,30,40): a device (20) for applying joining material to a component carrier (PCB), a placement device (30) for placing electronic components on the component carriers (PCB) and a joining device (40) for joining the electronic components to the component carriers (PCB), wherein the method comprises the following steps: receiving in each case at least one parameter value from each of the devices (20, 30,40) and storing the parameter values in a dataset (D) that is associated in each case with a defined number of component carriers (PCB) and with the resulting assemblies (1,2).

In some embodiments, the method further comprises comparing the parameter values of the respective dataset (D1, D2) with permissible ranges for the parameter values.

In some embodiments, the electronics production line (200) furthermore comprises the following devices (10,50): a provisioning device (10) for providing the component carriers (PCB) and a collecting device (50) for collecting the finished electronic assemblies (1,2).

In some embodiments, the electronics production line (200) comprises at least one inspection device (SPI), comprising: storing an inspection result of the inspection device in the dataset if the inspection is without findings and/or storing at least some raw data on which the inspection is based in the respective dataset (D1, D2) if the inspection has a finding.

In some embodiments, the receiving, the storing and/or the comparing are carried out by a system (100) that is arranged outside the devices.

In some embodiments, the method further comprises determining an adjustment of process parameters of the electronics production line (200) if at least single parameter values are outside the permissible range.

In some embodiments, the determining of the adjustment of process parameters comprises at least determining a line timing.

In some embodiments, a dataset (D1, D2) is created for each assembly (1,2).

In some embodiments, a respective common dataset (D1, D2) is created for similar assemblies (1,2).

In some embodiments, the datasets (D1, D2) comprise a combination of two or more of the following parameters: residual oxygen concentration, residual capacity in a collecting device (50), warp data relating to the component carriers (PCB), time and/or number of assemblies produced since the last maintenance and/or cleaning of the device for applying the joining material, throughput speed and/or line timing and joining material volume and/or mass and number of unplanned disruptions, interruptions and/or stoppages during ongoing operation.

In some embodiments, parameter values are received from at least two electronics production lines (200), the electronics production lines (200) producing variants of an assembly (1,2), or assemblies (1,2) of identical design.

As another example, some embodiments include a method for producing electronic assemblies (1,2), comprising: providing component carriers (PCB), applying joining material, placing components on the component carriers (PCB) and joining the components to the component carriers (PCB), wherein datasets (D1, D2) are recorded and evaluated for the production steps using a method as claimed in one of the preceding claims.

In some embodiments, each component carrier (PCB) and/or each assembly (1,2) is uniquely assigned a dataset (D1, D2) when the assemblies (1,2) are produced.

As another example, some embodiments include a system (100) for recording parameter values in at least one electronics production line (200), wherein the recording system (100) has at least one communication interface (110) for receiving parameter values and an evaluation device (120) designed to assign the parameter values to a stipulated number of component carriers (PCB) in a dataset (D1, D2).

In some embodiments, the system comprises another communication interface, which is designed to communicate with a multisensor measuring instrument, the multisensor measuring instrument being designed to go through the electronics production line (200) and supplying measured values that are assignable to a number of electrical assemblies (1,2), the evaluation device being designed so as to assign the measured values to the respective applicable datasets (D1, D2).

### BRIEF DESCRIPTION OF THE DRAWINGS

The teachings of the present disclosure are described and explained in more detail below on the basis of the exemplary embodiments depicted in the figures, in which:

FIG. 1 shows a schematic electronics production line; and

FIG. 2 shows an example system for recording parameter values incorporating teachings of the present disclosure.

### DETAILED DESCRIPTION

Example methods incorporating teachings of the present disclosure comprise: receiving in each case at least one parameter value from each of the devices and storing the parameter values in a dataset that is associated in each case with a defined number of component carriers and/or with the resulting assemblies. It has been found that combining a selection of parameter values from the production line into a single dataset has a significant advantage over the data and the evaluation remaining in the respective devices. This means that not only can the necessary examinations be centralized, but also optimizations that can already be applied for the next assemblies can be carried out during ongoing production. This allows the number of rejects to be reduced and the cycle time to be increased. In addition, it can also significantly simplify central data management for documentation and certification purposes.

Here, the parameter values are the values of the process parameters of the individual devices that are actually applied to the concrete component carriers during production. As such, the parameters or the parameter values thereof that can be used are the following exemplary variables, which can in turn be linked to (ranges of) serial numbers of the processed component carriers: throughput speed of the component carriers, number of processed component carriers in the current batch (e.g. since last modification/maintenance/break in production), curvature of the component carriers, information on the joining material (type, age and viscosity of paste, batch, etc.) application of joining material (squeegee direction, time since cleaning interval), number of components fitted, placement forces as extreme values (max/min) or dedicated placement forces for selected, e.g. sensitive, components, temperatures/temperature curves in the joining device, residual oxygen content, atmosphere in the joining device, and other parameter values relevant to the respective assembly.

In some embodiments, the method furthermore comprises comparing the parameter values of the respective dataset with permissible ranges for the parameter values. As such, not only can an easily manageable dataset be generated, but it can also be compared with applicable ranges. Furthermore, parameter values from multiple datasets can be examined for values that drift off. Thus, if certain parameter values remain very stable over a longer period of time and now drift off from a certain point in time, but are still in the permissible range, a need for action can be detected at an early stage.

In some embodiments, the production line comprises at least one provisioning device for providing the component carriers, for example an input stacker, and a collecting device for collecting the finished electronic assemblies, for example an output stacker. These devices also supply parameter values that can be received and stored in the dataset. The provisioning device can count the provided component carriers, for example, and the collecting device can accordingly count the finished assemblies.

In some embodiments, the production line comprises at least one inspection device. The method furthermore comprises storing an inspection result of the inspection device in the dataset if the inspection is without findings. This means in other words that there can be provision for a Boolean variable “Inspection OK” or “Inspection not OK”, where if the variable is set, it is documented that the inspection was without findings, i.e. the inspected assembly meets the required quality conditions. This is efficient in terms of data, and documents that the inspection was without findings for later purposes. In some embodiments, if the inspection device detects a finding, at least some of the raw data on which the inspection is based, that is to say images, for example, can be stored in the dataset as well. For example, they may be raw data relating to a poorly applied joining paste, a defective joint, a missing component, etc. This has the advantage that data directly linked to the other parameters that may have led to this error pattern exist, thus greatly simplifying diagnosis and making it easy to automate. The inspection devices may be optical or X-ray-based or other inspection devices here. Examples here are SPI (Solder Paste Inspection), automated X-ray inspection (AXI), etc.

In some embodiments, the receiving, the storing and/or comparing are carried out by a system that is arranged outside the devices, in particular outside the production line. In other words, the data recording and evaluation is carried out outside the production line in addition or as an alternative to the parameter value monitoring provided in the device. The storing here can also be carried out outside. Examples here are so-called EDGE boxes on the plant (not part of the plant), central recording systems in on-site production or even cloud-based systems. The advantage of receiving and evaluating outside the devices and/or the production line is the better comparability of the datasets and the greatly simplified evaluation capability.

In some embodiments, an adjustment of process parameters of the electronics production line is determined. This adjustment of the process parameters is determined in particular if at least single parameter values within a dataset are outside a permissible range.

In some embodiments, the determining of an adjustment of process parameters comprises at least determining a line timing. The line timing or the speed at which the component carriers are processed can be reduced or increased if the applicable parameters are outside a defined range. If for example a residual oxygen content is too high, the timing could be reduced to reverse a rising tendency of the residual oxygen.

In some embodiments, a dataset is created for each assembly, in particular exactly one dataset for each assembly. The applicable data that have been recorded for each individual electrical assembly are also systematically documented and made available accordingly. It is conceivable for each individual assembly to have a serial number or comparable identification to which the dataset can then be linked.

In some embodiments, a common dataset is created for similar assemblies, in particular identical assemblies. It is conceivable for this dataset to be used to store the parameter values that are identical and, if variances occur, for these to be identified and to be continuously stored accordingly. This is particularly efficient with regard to dataset size.

In some embodiments, the datasets have a combination of two or more of the following parameters: residual oxygen concentration, residual capacity in a collecting device, warp data relating to the component carriers, time and/or number of assemblies produced since the last maintenance and/or cleaning of the device for applying the joining material, throughput speed and/or line timing and joining material volume and/or mass, and number of unplanned disruptions, interruptions and/or stoppages during ongoing operation.

In some embodiments, parameter values are recorded from at least two electronics production lines that produce variants of an assembly, or assemblies of identical design. The parameter values can continue to be stored and evaluated. Assemblies are of identical design in particular if the layout of the assembly is identical and, for example, only the memory size (RAM/SSD/FLASH) is varied without the need to adjust the layout. If the performance (e.g. for power electronics) of the assembly differs, this may be a variant of an assembly, and the parameter values of the variants can be stored in the dataset. Here too, the comprehensive recording is of considerable advantage, since data are available in a structured form across assemblies and applicable findings can be obtained.

Some embodiments include a method for producing electronic assemblies. Producing the electronic assembly comprises here the production steps of providing component carriers, applying joining material, placing components on the component carriers and joining the components to the component carriers. For the production steps, datasets are recorded and evaluated here using one of the methods that are described herein. Production of the assemblies directly results in datasets being available that can be documented and evaluated with regard to the quality and optimization of the assemblies.

In some embodiments, each component carrier and/or each assembly is uniquely assigned a dataset when the assemblies are produced. This not only has the advantage that a single dataset exists for each of the assemblies for quality control directly after production, but also has the advantage for further tracking that the production data or the relevant process parameters are documented and traceable. This is a considerable advantage, especially for tracing applications.

Some embodiments include a system for recording parameter values in at least one electronics production line. The recording system has here at least one communication interface for receiving parameter values. The communication interface may be in the form of an industrial communication interface, for example Profinet, Profibus, WLAN or other wireless and/or wired communication interfaces here. The recording system furthermore has an evaluation device that receives the parameter values from the communication interface and is designed to assign and store the parameter values for a dataset or to store them in a dataset. In particular, the evaluation unit may be designed such that as part of the method according to the invention it selects data for permanent storage in the dataset or rejects them because they have no relevance to the dataset. The datasets are each created here for a stipulated number of component carriers or assemblies and can combine here similar or identical groups of assemblies, but it is also conceivable for a separate dataset to be created for each individual assembly or for each individual component carrier.

In some embodiments, the system has another communication interface, which is designed to communicate with a multisensor measuring instrument. The multisensor measuring instrument is designed to go through the electronics production line and supplies here measured values of parameters that affect the electronic assemblies or the component carriers. The evaluation device is designed here in such a way that the measured values can be assigned to the respective applicable datasets and can be stored therein. As such, not only do the datasets provide the data that originally come from the devices, but they are also enhanced with measured values that reflect the actual conditions in the plant.

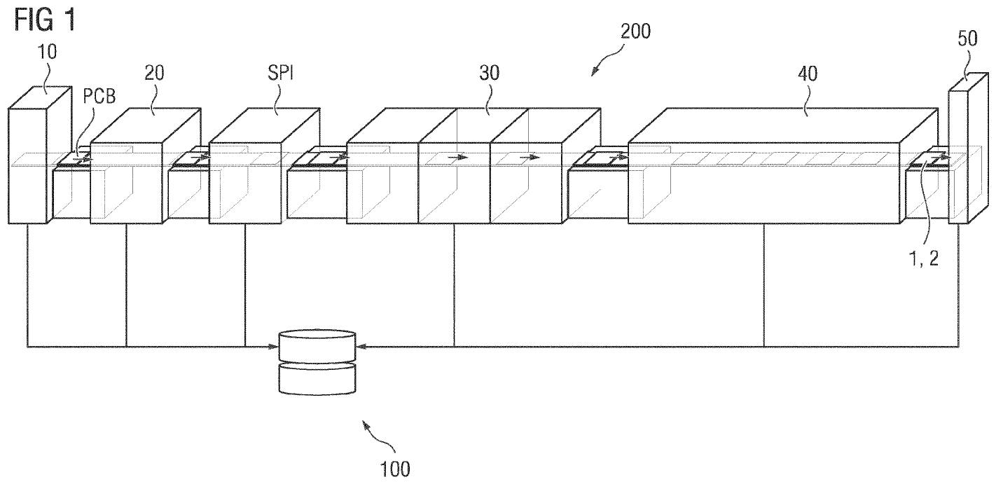

FIG. 1 shows a schematic electronics production line 200 as are used in large numbers as such or in a similar form. From left to right, the electronics production line 200 has a provisioning device 10 designed to provide component carriers PCB, that is to say, for example, printed circuit boards or other substrates. Such devices may be in the form of input stackers, for example. Furthermore, a device 20 for applying joining material is shown that applies joining material to the component carriers PCB; this may be, for example, a stencil printer for applying solder paste.

An inspection device SPI is arranged after the device for applying joining material; in this case this may be a solder paste inspector that assesses the quality of the application of joining material on the basis of optical methods, for example. Subsequently, a placement device 30 is shown that places electrical components on the component carriers PCB now provided with joining material. After the placement device 30, a joining device 40 can be seen, this being able to be a reflow furnace that melts the joining materials and thus attains an electrical and mechanical connection between the electrical components and the component carriers PCB. The resulting electrical assemblies 1,2 thus reach the end of the electronics production line, for which a collecting device 50 is available. When this is in the form of an output stacker, for example, the finished electronic assemblies 1,2 can be collected and stacked. Furthermore, a system 100 for recording parameter values of the electronics production line 200 is connected to each of the devices 10, . . . , 50 via communication connections. The system 100 can thus receive, preselect and/or evaluate applicable parameter values from all devices 10, . . . , 50. In some embodiments, a single system 100 is available for multiple production lines.

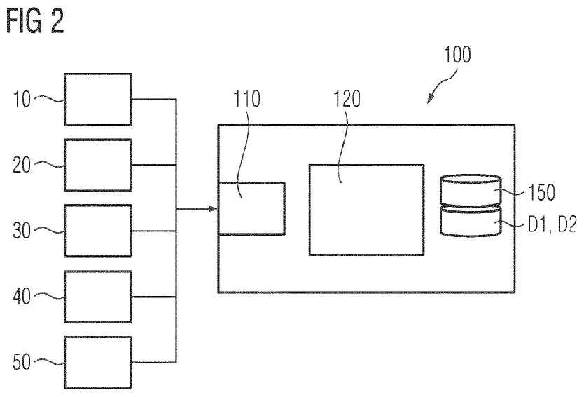

FIG. 2 shows an example system 100 for recording parameter values as is used in FIG. 1 incorporating teachings of the present disclosure. It now schematically depicts the devices 10, . . . , 50, which each communicate with a communication interface 110. This communication interface 110 can be used to make available parameter values or other measured values from the devices directly. An evaluation device 120 is designed so as to assign each of the received parameter values to at least a number of component carriers or the resulting electronic assemblies and to store them in a dataset D1, D2 accordingly. It is furthermore conceivable for the evaluation device 120 to use continuous flows of parameter values to determine applicable key figures, which can then in turn be stored in the dataset D1, D2. The values are assigned here to a certain number of electronic assemblies 1, 2 accordingly, just like the entire dataset D1, D2, and thus allow direct traceability of the parameter values. Furthermore, there is provision for a database 150 designed to store the datasets D1, D2. Such a database can be implemented either locally or in server-based fashion.

In summary, the present disclosure teaches systems and methods for recording and evaluating parameter values in at least one electronics production line (200), the electronics production line (200) comprising devices (20, 30, 40) to produce electronic assemblies (1,2). In order to improve and simplify the recording and in particular the evaluation of parameter values, an example method includes: receiving in each case at least one parameter value from each of the devices (20, 30, 40), storing the parameter values in a dataset (D) that is associated in each case with a defined number of component carriers (PCB) and with the resulting assemblies (1,2), and comparing the parameter values of the respective dataset (D1, D2) with permissible ranges for the parameter values.

### REFERENCE SIGNS

10 provisioning device
20 device for applying joining material
30 placement device
40 joining device
50 collecting device
SPI inspection device
PCB component carrier
1,2 electronic assemblies
D1, D2 dataset of the parameter values
100 system for recording and evaluating parameter values
110 communication interface
120 evaluation device
150 database
200 electronics production line

What is claimed is:

1. A method for recording and evaluating parameter values in an electronics production line to produce electronic assemblies, the production line including
a dispenser for applying joining material to a component carrier,
a placement device for placing electronic components on the component carrier, and
joining device to join the electronic components to the component carrier,
the method comprising:
receiving a parameter value from each of the devices; and
storing the parameter values in a dataset associated with a defined number of component carrier and with the resulting assemblies.

2. The method as claimed in claim 1, further comprising comparing the parameter values of the respective dataset with permissible ranges for the parameter values.

3. The method as claimed in claim 1, wherein the electronics production line further comprises:
a provisioning device to provide the component carriers; and
a collecting device to collect the finished electronic assemblies.

4. The method as claimed in claim 1, wherein the electronics production line comprises an inspection device; and
the method further comprises:
storing an inspection result of the inspection device in the dataset if the inspection is without findings; and
storing raw data on which the inspection is based in the respective dataset if the inspection has a finding.

5. The method as claimed in claim 1, wherein receiving, the storing and/or the comparing are carried out by a system arranged outside the devices.

6. The method as claimed in claim 1, further comprising determining an adjustment of process parameters of the electronics production line if a parameter value is outside the permissible range.

7. The method as claimed in claim 4, wherein determining the adjustment of process parameters comprises determining a line timing.

8. The method as claimed in claim 1, further comprising creating a dataset for each assembly.

9. The method as claimed in claim 1, further comprising creating respective common dataset for similar assemblies.

10. The method as claimed in claim 1, wherein the datasets comprise a combination of two or more of the following parameters:
residual oxygen concentration,
residual capacity in a collecting device,
warp data relating to the component carriers,
time and/or number of assemblies produced since the last maintenance and/or cleaning of the device for applying the joining material,
throughput speed and/or line timing, and
joining material volume and/or mass, and
number of unplanned disruptions, interruptions and/or stoppages during ongoing operation.

11. The method as claimed in claim 1, further comprising receiving parameter values from at least two electronics production lines producing variants of an assembly or assemblies of identical design.

12. A method for producing electronic assemblies, the method comprising:
providing component carriers;
applying joining material;
placing components on the component carriers;
joining the components to the component carriers;
receiving a parameter value from each of the devices; and
storing the parameter values in a dataset associated with a defined number of component carrier and with the resulting assemblies.

13. The method as claimed in claim 11, further comprising assigning each component carrier and/or each assembly a unique dataset when the assemblies are produced.

14. A system for recording parameter values in an electronics production line, the system comprising:
a communication interface for receiving parameter values; and
an evaluation device designed to assign the parameter values to a stipulated number of component carriers in a dataset.

15. The system as claimed in claim 13, further comprising another communication interface to communicate with a multisensor measuring instrument;
wherein the multisensor measuring instrument measures operating parameters of the electronics production line and supplies measured values assignable to a number of electrical assemblies;
wherein the evaluation device assigns the measured values to the respective applicable datasets.
